(19) United States
(12) Patent Application Publication
(10) Pub. No.: US 2007/0176618 A1
(43) Pub. Date: Aug. 2, 2007

(54) Universal contactor for use with multiple handlers and method therefor

(75) Inventors: Daniel R. Adney, Phoenix, AZ (US); Rodger E. Kells, Chandler, AZ (US)

Correspondence Address: WEISS & MOY PC, 4204 NORTH BROWN AVENUE, SCOTTSDALE, AZ, 85251, US

(73) Assignee: AMKOR TECHNOLOGY, INC.

(21) Appl. No.: 11/203,517

(22) Filed: Aug. 12, 2005

(51) Int. Cl. G01R 31/02

(52) U.S. Cl. 324/761

(57) ABSTRACT

A universal contact element for use on multiple handlers has a contactor body. A cavity is formed in a central area of the contactor body for holding semiconductor devices of a predetermined size. A first plurality of channels is formed in the cavity and extends through the contactor body. A plurality of contact pins is provided. A contact pin is positioned inside each of the first plurality of channels. A plurality of alignment pins is positioned around the outer perimeter of the contactor body outside of the cavity. The plurality of alignment pins is positioned around the top surface of the contactor body to conform to different alignment openings on multiple handlers. A retainer plate is coupled to a bottom surface of the contactor body for keeping the plurality of contact pins inside each of the plurality of first channels.

### FIELD OF THE INVENTION

This invention relates to a contact element for a semiconductor handler and, more specifically, to a universal contactor which is interchangeable and may be mounted to a plurality of different semiconductor handlers.

### BACKGROUND OF THE INVENTION

The testing of an integrated circuit device is a very important step in the production of quality semiconductor devices. A number of different tests may be performed on the integrated circuit device to identify whether the circuit is operating correctly and whether or not the circuit is likely to malfunction in the future.

When testing the integrated circuit device, a contact element is mounted to a body of a handler. The handler feeds the integrated circuit device to a piece of testing equipment. The testing equipment will then send test signals to the integrated circuit device and monitor the test signals from the integrated circuit device in order to see if the integrated circuit device is functioning properly.

A problem arises since each handler body typically has special features that are required for each handler. Typical features may be mounting holes, alignment holes, contactor body size, etc. Thus, different types of handlers require different contactors per design type due to the unique mounting and alignment features of each handler. For example, when testing two different devices of similar size using two different handlers, two different contactors would need to be designed having the same center area but having different alignment and mounting features. Producing two different contactors having the same center area but having different alignment and mounting features for each handler increases the cost of testing and hence production of the different integrated circuit devices.

Therefore, a need existed to provide a device and method to overcome the above problem.

### SUMMARY OF THE INVENTION

A universal contact element for use on multiple handlers has a contactor body. A cavity is formed in a central area of the contactor body for holding semiconductor devices of a predetermined size. A first plurality of channels is formed in the cavity and extends through the contactor body. A plurality of contact pins is provided. A contact pin is positioned inside each of the first plurality of channels. A plurality of alignment pins is positioned around the outer perimeter of the contactor body outside of the cavity. The plurality of alignment pins is positioned around the top surface of the contactor body to conform to different alignment openings on multiple handlers. A retainer plate is coupled to a bottom surface of the contactor body for keeping the plurality of contact pins inside each of the plurality of first channels.

The present invention is best understood by reference to the following detailed description when read in conjunction with the accompanying drawings.

### BRIEF DESCRIPTION OF THE DRAWINGS

FIG. 1 is an elevated perspective view of the universal contact element of the present invention;

FIG. 2 is an exploded view of the universal contact element of the present invention;

FIG. 3A is an elevated exploded view of the universal contact element of the present invention mounted on a first type of handler body; and

FIG. 3B is an elevated exploded view of the universal contact element of the present invention mounted on a second type of handler body.

Common reference numerals are used throughout the drawings and detailed description to indicate like elements.

### DETAILED DESCRIPTION

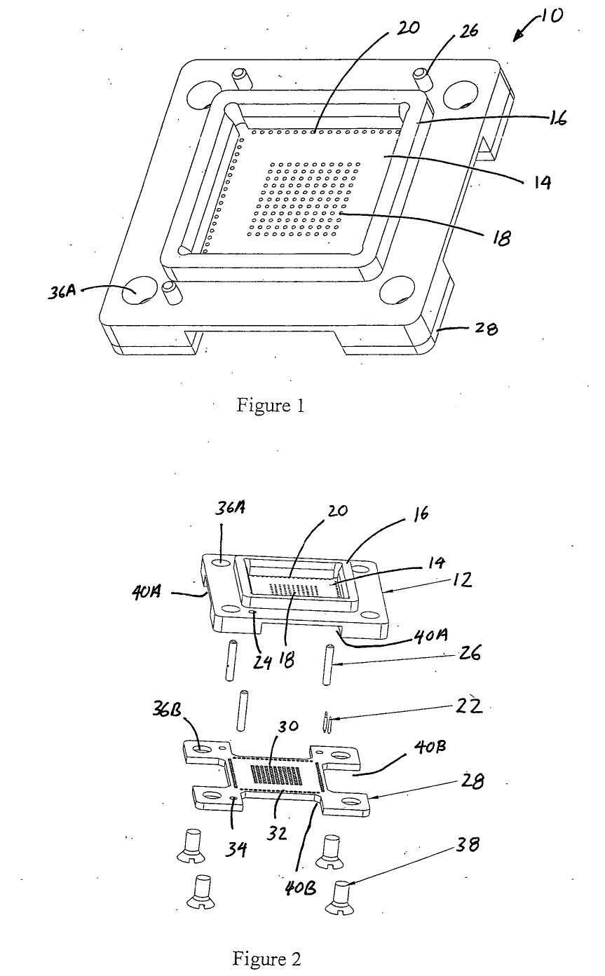

Referring to FIG. 1, a universal contact element 10 (hereinafter contact element 10) is shown. The contact element 10 allows for similar size semiconductor devices to be placed on different handlers using the same contact element 10 even though each handler may have different mounting and alignment features.

The contact element 10 has a base 12. The base 12 is generally made out of a lightweight non-conductive material. In general, the base 12 is made out of plastic or the like. The listing of the above should not be seen as to limit the scope of the present invention. The base 12 has a cavity 14 formed therein. The cavity 14 is generally formed in a central region of the base 12. The cavity 14 is of sufficient size to house semiconductor devices of a predetermined size. A ridge 16 is formed around a top perimeter of the cavity 14. The ridge 16 is used to align a semiconductor device in the cavity 14. The cavity 14 and ridge 16 emulate a footprint of the semiconductor device to be tested.

A plurality of first channels 18 are formed in a bottom area of the cavity 14. The channels 18 are hollow passageways formed through the bottom surface of the cavity 14. The location of the channels 18 align with contacts on one side of the semiconductor device when the semiconductor device is placed in the cavity 16. In accordance with one embodiment of the present invention, a first set of the channels 18 are formed in a central area of the cavity 14. A second set of the channels 20 are formed around an outer perimeter of the cavity 14. The channels 18 and 20 are formed to emulate the different contact platforms of different semiconductor devices.

A contact pin 22 is placed inside each channel 18 and 20. The contact pins 22 are double sided contact pins. One side of the contact pin 22 is used to make contact with the contacts on one side of the semiconductor device. The second end of the contact pin 22 is used to contact a test board which is coupled to the contact element 10. In general, the contact pins 22 are doubled ended spring contacts.

A plurality of third channels 24 are formed around the outer perimeter of the base 12 outside of the cavity 14. The plurality of third channels 24 are hollow passageways formed through the height of the base 12. An alignment pin 26 is placed inside each of the third channels 24. The alignment pin 26 extends up from the top surface of the base 12. The alignment pins 26 are used to properly align the contact element 10 onto different handler bodies. When the contact element 10 is properly aligned with a handler body, the alignment pins 26 will extend up and into alignment holes formed in the handler body. The alignment pins 26 are generally formed out of a non-conductive material. In general, the alignment pins 26 are formed out of the same material as the base 12.

A retainer plate 28 is coupled to a bottom surface of the base 12. The retainer plate 28 is used to keep the contact pins 22 and alignment pins 26 in the respective channels 18, 20 and 24. Thus, the retainer plate 28 is used to keep the contact pins 22 and the alignment pins 26 from falling out of the base 12. The retainer plate 28 is further used to allow the second side of the contact pins 22 to contact a test board which may be coupled to bottom section of the retainer plate 28 during testing of the semiconductor device.

In order to allow the second side of the contact pins 22 to contact a test board, the retainer plate 28 will have a plurality of openings formed through the retainer plate 28. The retainer plate 28 will have a first plurality of openings 30. The first plurality of openings 30 are formed in a central area of the retainer plate 28. The first plurality of openings 30 are aligned with the first channels 18 formed in a bottom area of the cavity 14. The retainer plate 28 has a second plurality of openings 32 formed through the retainer plate 28. The second plurality of openings 32 are formed around the outer perimeter of the central area of the retainer plate 28. The second plurality of openings 32 are aligned with the second plurality of channels 20 formed around the outer perimeter of the cavity 14. The first plurality of openings 30 and the second plurality of openings 32 will allow test signals to be sent to the semiconductor device positioned in the cavity 14 via the contact pins 20.

The retainer plate 28 may have one or more retaining cavities 34 formed therein. The retaining cavities 34 are positioned around an outer perimeter of the retainer plate 28. The retaining cavities 34 are aligned with the plurality of third channels 24 formed around the outer perimeter of the base 12 outside of the cavity 14. The retaining cavities 34 are used to hold the alignment pins 26 in the retainer plate 28.

The retainer plate 28 is removably coupled to the bottom surface of the base 12. Connectors 38 are used to couple the retainer plate 28 to the bottom surface of the base 12. In general, a screw or other device is used to couple the retainer plate 28 to the bottom surface of the base 12. Connector openings 36A are formed in the base 12. Corresponding connector openings 36B are formed through the retainer plate 28. Once the retainer plate 28 is properly aligned with the bottom surface of the base 12, the connector openings 36A in the base 12 will be aligned with a respective connector opening 36B in the retainer plate 28. Once the connector openings 36A and 36B are aligned, the connectors 38 are placed through the connector openings 36A and 36B to secure the retainer plate 28 to the bottom surface of the base 12.

One or more notches 40A are formed in the base 12. The notches 40A are generally formed around the outer perimeter of the base 12 towards a bottom surface thereof. Corresponding notches 40B are formed in the retainer plate 28. The notches 40B are generally formed around the outer perimeter of the retainer plate 28. Once the retainer plate 28 is properly aligned with the bottom surface of the base 12, the notches 40A in the base 12 will be aligned with respective notches 40B formed in the retainer plate 28. The notches 40A and 40B are formed so discrete components may be placed close to the integrated circuit device being tested.

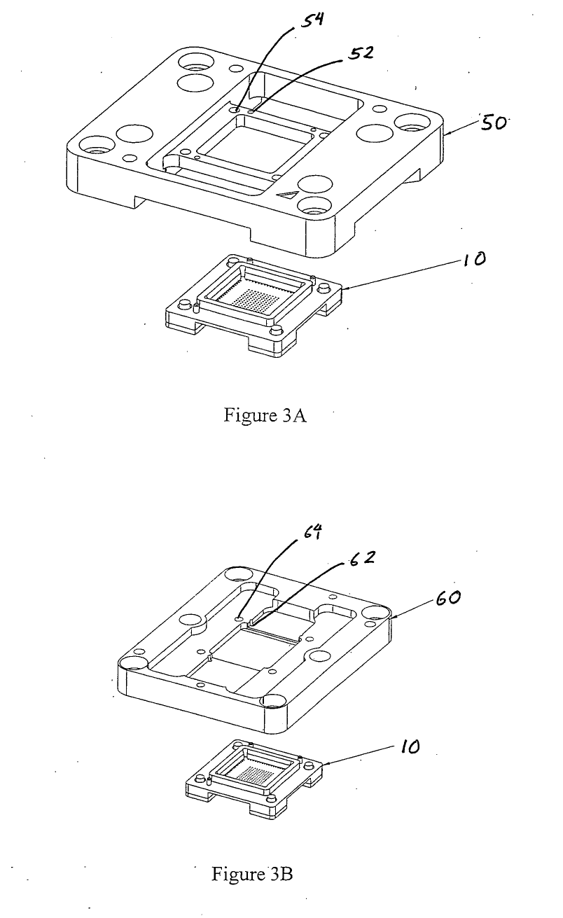

Referring to FIG. 3, the contact element 10 is shown being coupled to a handler body 50. In the embodiment shown in FIG. 3, the handler body 50 is a Multitest 9918 handler body. The contact element 10 needs to be properly aligned with the handler body 50. Thus, the alignment pins 26 are aligned with alignment holes 52 formed in the handler body 50. When properly aligned, the alignment pins 26 will extend up and into the alignment holes 52. Also, once the contact element 10 is properly aligned, the connectors 38 will extend up and into openings 54 formed in the handler body 50.

As may be seen from FIG. 3, the handler body 50 has notches 54 located around the lower perimeter of the handler body 50. Thus, the notches 40A formed in the base 12 and the corresponding notches 40B formed in the retainer plate 28 will align with the notches 54 in the handler body 50. Thus, the notches 40A and 40B allow the contact element 10 to fit in and be coupled to the handler body 50.

Referring to FIG. 4, the contact element 10 is shown being coupled to another handler body 60. In the embodiment shown in FIG. 4, the handler body 60 is a RASCO 1000/2000 handler body. The contact element 10 needs to be properly aligned with the handler body 60. Thus, the alignment pins 26 are aligned with alignment holes 62 formed in the handler body 60. When properly aligned, the alignment pins 26 will extend up and into the alignment holes 62. Also, once the contact element 10 is properly aligned, the connectors 38 will extend up and into openings 64 formed in the handler body 60.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

1. A universal contact element for use on multiple handlers comprising:
a contactor body;
a cavity formed in a central area of the contactor body for holding semiconductor devices of a predetermined size;
a first plurality of channels formed in the cavity and extending through the contactor body, the first plurality of channels comprising:
a first set of channels formed in a central area of the cavity and extending through the contactor body; and
a second set of channels formed around an outer perimeter of the cavity and extending through the contactor body;
a plurality of contact pins, wherein a contact pin is positioned inside each of the first plurality of channels;
a plurality of alignment openings formed along an outer perimeter of contactor body outside of the cavity to conform to different alignment openings on multiple handlers;
a plurality of alignment pins, wherein an alignment pin is positioned inside each of the plurality of alignment openings, the plurality of alignment pins positioned around the top surface of the contactor body to align the contact element on multiple handlers; and
a retainer plate coupled to a bottom surface of the contactor body for keeping the plurality of contact pins inside each of the plurality of first channels.

2. A universal contact element for use on multiple handlers in accordance with claim 1, further comprising a ridge extending around a perimeter of the cavity, the cavity and the ridge forming a footprint of the semiconductor devices.

3. A universal contact element for use on multiple handlers in accordance with claim 1, further comprising:
first plurality of notches located around a lower perimeter of the contactor body; and
second plurality of notches formed in the retainer plate, the second plurality of notches aligning with the first plurality of notches, the first plurality of notches and the second plurality of notches allowing the universal contact element to fit in and be coupled to multiple handlers.

4. (canceled)

5. A universal contact element for use on multiple handlers in accordance with claim 1, further comprising a second plurality of channels formed in the retainer plate, the second plurality of channels aligned with the first plurality of channels when the retainer plate is coupled to the contactor body.

6. A universal contact element for use on multiple handlers in accordance with claim 1, further comprising a plurality of alignment holes formed in the retainer plate, the plurality of alignment holes aligned with the plurality of alignment openings formed in the contactor body when the retainer plate is coupled to the contactor body, the plurality of alignment holes used to hold the plurality of alignment pins in the retainer plate.

7. A universal contact element for use on multiple handlers in accordance with claim 1, further comprising:
first set of connector openings formed through the contactor body and located around the outer perimeter of the contactor body;
second set of connector openings formed through the retainer plate, the second set of connector openings aligning with the first set of connector openings; and
plurality of connectors positioned through the first and second sets of connector openings for coupling the retainer plate to the contactor body.

8. A universal contact element for use on multiple handlers in accordance with claim 1, wherein the contactor body is made of a non-conductive material.

9. A universal contact element for use on multiple handlers in accordance with claim 1, wherein the cavity has a solid surface area between the first set of channels and the second set of channels.

10. A universal contact element for use on multiple handlers comprising:
a contactor body;
a cavity formed in a central area of the contactor body for holding semiconductor devices of a predetermined size;
a first plurality of channels formed in the cavity and extending through the contactor body, the first plurality of channels comprising:
a first set of channels formed in a central area of the cavity and extending through the contactor body; and
a second set of channels formed around an outer perimeter of the cavity and extending through the contactor body;
a plurality of contact pins, wherein a contact pin is positioned inside each of the first plurality of channels;
a plurality of alignment openings formed along an outer perimeter of contactor body outside of the cavity to conform to different alignment openings on multiple handlers;
means positioned inside each of the plurality of alignment openings for aligning the universal contact element to different alignment openings on multiple handlers; and
means coupled to a bottom surface of the contactor body for keeping the plurality of contact pins inside each of the plurality of first channels.

11. (canceled)

12. A universal contact element for use on multiple handlers comprising:
a contactor body;
a cavity formed in a central area of the contactor body for holding semiconductor devices of a predetermined size;
a ridge extending around a perimeter of the cavity, the cavity and the ridge forming a footprint of the semiconductor devices;
a first plurality of channels formed in the cavity and extending through the contactor body, the first plurality of channels comprising:
a first set of channels formed in a central area of the cavity and extending through the contactor body; and
a second set of channels formed around an outer perimeter of the cavity and extending through the contactor body;
a plurality of contact pins, wherein a contact pin is positioned inside each of the first plurality of channels;
a plurality of alignment openings formed along an outer perimeter of contactor body outside of the cavity to conform to different alignment openings on multiple handlers;
a plurality of alignment pins, an alignment pin is positioned inside each of the plurality of alignment openings, the plurality of alignment pins positioned around the top surface of the contactor body to align the contact element on multiple handlers;
a retainer plate coupled to a bottom surface of the contactor body for keeping the plurality of contact pins inside each of the plurality of first channels;
a first plurality of notches located around a lower perimeter of the contactor body; and
a second plurality of notches formed in the retainer plate, the second plurality of notches aligning with the first plurality of notches, the first plurality of notches and the second plurality of notches allowing the universal contact element to fit in and be coupled to multiple handlers.

13. (canceled)

14. A universal contact element for use on multiple handlers in accordance with claim 12, further comprising a second plurality of channels formed in the retainer plate, the second plurality of channels aligned with the first plurality of channels when the retainer plate is coupled to the contactor body.

15. A universal contact element for use on multiple handlers in accordance with claim 14, further comprising a plurality of alignment holes formed in the retainer plate, the plurality of alignment holes aligned with the plurality of alignment openings formed in the contactor body when the retainer plate is coupled to the contactor body, the plurality of alignment holes used to hold the plurality of alignment pins in the retainer plate.

16. A universal contact element for use on multiple handlers in accordance with claim 12, further comprising:
a first set of connector openings formed through the contactor body and located around the outer perimeter of the contactor body;
a second set of connector openings formed through the retainer plate, the second set of connector openings aligning with the first set of connector openings; and
a plurality of connectors positioned through the first and second sets of connector openings for coupling the retainer plate to the contactor body.

17. A universal contact element for use on multiple handlers in accordance with claim 12, wherein the contactor body is made of a non-conductive material.

18. A universal contact element for use on multiple handlers in accordance with claim 12, wherein the cavity has a solid surface area between the first set of channels and the second set of channels.

19. A universal contact element for use on multiple handlers in accordance with claim 10, further comprising a first plurality of notches located around a lower perimeter of the contactor body.

20. A universal contact element for use on multiple handlers in accordance with claim 19, a second plurality of notches formed in the means coupled to the bottom surface of the contactor body, the second plurality of notches aligning with the first plurality of notches, the first plurality of notches and the second plurality of notches allowing the universal contact element to fit in and be coupled to multiple handlers.

21. A universal contact element for use on multiple handlers in accordance with claim 10, further comprising a plurality of alignment holes formed in the means coupled to the bottom surface of the contactor body, the plurality of alignment holes aligned with the plurality of alignment openings formed in the contactor body when the means coupled to the bottom surface of the contactor body is coupled to the contactor body.

22. A universal contact element for use on multiple handlers in accordance with claim 10, further comprising:
first set of connector openings formed through the contactor body and located around the outer perimeter of the contactor body;
a second set of connector openings formed through the means coupled to the bottom surface of the contactor body, the second set of connector openings aligning with the first set of connector openings; and
a plurality of connectors positioned through the first and second sets of connector openings for coupling the means coupled to the bottom surface of the contactor body to the contactor body.

23. A universal contact element for use of multiple handlers in accordance with claim 10, wherein the contactor body is made of a non-conductive material.

24. A universal contact element for use on multiple handlers in accordance with claim 1, wherein the cavity has an area unpopulated with channels between the first set of channels and the second set of channels.

25. A universal contact element for use on multiple handlers in accordance with claim 1, wherein the cavity has an area devoid of channels between the first set of channels and the second set of channels.

26. A universal contact element for use on multiple handlers in accordance with claim 1, wherein the cavity has an area uninhabited with channels between the first set of channels and the second set of channels.
